(19) United States
(12) Patent Application Publication
(10) Pub. No.: US 2019/0185679 A1
(43) Pub. Date: Jun. 20, 2019

(54) WATER BASED COATING

(71) Applicants: John W. Swanson, Lake Oswego, OR (US); Timothy Krytenberg, Ridgefield, WA (US)

(72) Inventors: John W. Swanson, Lake Oswego, OR (US); Timothy Krytenberg, Ridgefield, WA (US)

(73) Assignee: Industrial Control Development, Inc., Ridgefield, WA (US)

(21) Appl. No.: 16/218,238

(22) Filed: Dec. 12, 2018

Related U.S. Application Data
(60) Provisional application No. 62/599,561, filed on Dec. 15, 2017.
(60) Provisional application No. 62/702,199, filed on Jul. 23, 2018.

(51) Int. Cl. C09D 1/00; C09D 7/20; C09D 7/61; H01L 31/0216

(52) U.S. Cl. CPC C09D 1/00; C09D 7/20; C03C 17/256; H01L 31/0216; C09D 7/61

(57) ABSTRACT

A heat curable aqueous composition comprising:
(a) water;
(b) at least 5 wt % sodium pyrophosphate, at least 5 wt % sodium phosphate monobasic, at least 5 wt % sodium triphosphate, at least 5 wt % monoammonium phosphate, at least 5 wt % diammonium phosphate, or at least 5 wt % of a mixture thereof, based on the total weight of the composition including the weight of the water; and
(c) at least one pigment, or at least one metal-containing ingredient, or a mixture of at least one pigment and at least one metal-containing ingredient.

### CROSS REFERENCE TO RELATED APPLICATION

This application claims the benefit of U.S. Provisional Application No. 62/599,561, filed Dec. 15, 2017, and U.S. Provisional Application No. 62/702,199, filed Jul. 23, 2018, both of which are incorporated herein by reference in their entirety.

### BACKGROUND

High temperature ceramic coatings for ceramic tile and glass are limited to the use of ceramic enamel (pigmented glass frit mixed with solvents and other coating modifiers) coating compositions or silicate-based coating compositions. Ceramic enamel coating compositions consist of primarily solvent and is known in the industry to weaken glass substrates from 20% to 50%. Silicate-based coatings also weaken the glass but are diluted with water as opposed to solvent.

### SUMMARY

Disclosed herein is a heat curable aqueous composition comprising:

(a) water;

(b) at least 5 weight % sodium pyrophosphate, at least 5 weight % sodium phosphate monobasic, at least 5 weight % sodium triphosphate, at least 5 weight % monoammonium phosphate, at least 5 weight % diammonium phosphate, or at least 5 weight % of a mixture thereof, based on the total weight of the composition including the weight of the water; and

(c) at least one pigment, or at least one metal-containing ingredient, or a mixture of at least one pigment and at least one metal-containing ingredient.

Also disclosed herein are methods of applying the composition to a substrate.

Further disclosed herein is an article comprising a substrate and a coating disposed on a surface of the substrate, wherein the coating is formed from the composition.

### DETAILED DESCRIPTION

Disclosed herein are compositions for applying to substrates such as glass, ceramic, textile, monofilament, multifilament, polymeric, metal, wood, and combinations thereof. In certain embodiments, the compositions are particularly useful for digitally printing images or coating onto a substrate. The compositions are particularly useful for applying to glass, ceramic, wood, composites and metal substrates. The compositions disclosed herein are heat curable aqueous compositions. In certain embodiments, the compositions can be applied at room temperature and cured at a high temperature (e.g, at least 420° C., more particularly at least 650° C.; up to 750° C.). In certain embodiments, the compositions can be applied at room temperature and at neutral pH (e.g., 6.5 to 7.5, more particularly 6.9 to 7.1, most particularly 7). In other embodiments, the compositions can be applied at a pH of 3.0 to 7.5, more particularly 3.5 to 7.2. In certain embodiments, the compositions provide a very opaque coating with thinner coatings as compared to present ceramic enamel (frit based) coatings. In certain embodiments, the coating composition provides a coating that may not weaken the substrate, especially a glass substrate, to as great a degree as ceramic enamel and silicate coatings. In certain embodiments, the composition may strengthen a substrate consisting of glass and/or ceramic.

In certain embodiments, the compositions are a water based phosphate-containing coating for high temperature applications that is intended to be attached to glass and ceramic surfaces. The phosphate bonds the metal-containing ingredient in the coating.

The phosphate included in the composition may be a sodium pyrophosphate. The sodium pyrophosphate may be sodium pyrophosphate dibasic, sodium pyrophosphate tetrabasic or a mixture thereof. In certain embodiments, the phosphate included in the composition may be sodium triphosphate. In certain embodiments, the phosphate included in the composition may be sodium phosphate monobasic. In certain embodiments, the phosphate included in the composition may be monoammonium phosphate. In certain embodiments, the phosphate included in the composition may be diammonium phosphate. In certain embodiments, a mixture of at least two different phosphates may be included. In certain embodiments, the composition includes (i) at least one of sodium pyrophosphate, sodium phosphate monobasic, or sodium triphosphate, and (ii) at least one of monoammonium phosphate or diammonium phosphate. In certain embodiments, the phosphate is present in an amount of at least 5 weight %, particularly at least 8 weight %, based on the total weight of the composition including the weight of the H₂O. In certain embodiments, the phosphate is present in an amount of at least 10 weight %, particularly at least 20 weight %, based on the total dry weight of the composition. In certain embodiments, the phosphate is present in an amount not greater than 20 weight %, particularly not greater than 15 weight %, based on the total weight of the composition including the weight of the H₂O. In certain embodiments, the phosphate is present in an amount not greater than 40 weight %, particularly not greater than 30 weight %, based on the total dry weight of the composition.

The compositions may also include at least one metal-containing ingredient. In certain embodiments the metal-containing ingredient is or includes a transition metal element, a post transition metal element, a metalloid element, or a mixture thereof. Illustrative transition elements include Sc, Ti, V, Cr, Mn, Fe, Co, Ni, Cu, Zn, Y, Zr, Nb, Mo, Tc, Ru, Rh, Pd, Ag, Cd, La, Hf, Ta, W, Re, Os, Ir, Pt, Au and Hg. Illustrative post transition elements include Al, Ga, Ge, In, Sn, Sb, Tl, Pb, Bi, and Po. Illustrative metalloid elements include B, Si, Ge, As, Sb, Te, and to a lesser extent C, Se, Po, At. In certain embodiments, the metal-containing ingredient is a transition metal oxide, transition metal halide, transition metal hydrate or transition metal phosphate. In certain embodiments, the post transition metal compound is a post transition metal oxide, post transition metal halide, post transition metal hydrate or post transition metal phosphate. Particularly preferred metal-containing ingredients include titanium dioxide, manganese oxide (Mn₂O₃), iron (III) oxide, zinc oxide, aluminum oxide (Al₂O₃), bismuth aluminate hydrate and aluminum phosphate.

In certain embodiments, the composition includes 0.25 to 2 weight %, particularly 0.5 to 1 weight %, of at least one transition metal compound, post transition metal compound or metalloid compound, based on the total weight of the composition including the weight of the H₂O. In certain embodiments, the composition includes 0.5 to 4 weight %, particularly 1.0 to 2 weight %, of at least one transition metal compound, post transition metal compound, or metalloid compound based on the total dry weight of the composition. Although not bound by any theory, it is believed that the transition metal compound, post transition metal compound, or metalloid compound may increase the bond density within the coating.

In certain embodiments the metal-containing ingredient is mixed metal oxide. The mixed metal oxide may be a mixed metal oxide pigment. Mixed metal oxide pigments are compounds comprised of a group of two or more metals and oxygen. The most common crystal structures are rutile (MeO₂) hematite (Me₂O₃) or spinel (Me₃O₄). Metals commonly present include: cobalt, iron, trivalent chrome, tin, antimony, titanium, manganese and aluminum. Illustrative mixed metal oxide pigments include the following shown below in Table 1:

| Color | Pigment | C.I. Pigment | CAS # | Manufacturer | Pigment type |
|---|---|---|---|---|---|
| Black | Nubifer NB- | | | Nubiola/Ferro | iron oxides |
| | 5970 | | | | |
| Black | Monarch 1000 | | | Cabot | carbon black |
| Black | 303T | Bayferrox ® | 68186- | | iron and manganese oxide |
| | | 303 T | 94-7 | | (Fe,Mn)₂0₃ |
| Black | 30C965 | Black 28 | 68186- | Shepherd | |
| | | | 91-4 | | |
| White | 1000 | Kronos 1000 | 13463- | | titanium dioxide |
| | | | 67-7 | | |
| Brown | Brown 10P850 | Yellow 164 | | Shepherd | Manganese Antimony Titanium Buff |
| | | | | | Rutile |
| Yellow | Nubifer Y- | | | Nubiola/Ferro | iron oxides |
| | 7050 | | | | |
| Yellow | 30C236 | Brown 24 | 68186- | | Chromium antimony and titanium |
| | | | 90-3 | | |
| Blue | Blue 385 | Blue 28 | 1345-16-0 | Shepherd | Cobalt Aluminate Blue Spinel |
| Blue | Blue 211 | Blue 36 | 68187- | Shepherd | Cobalt Chromite Blue-Green Spinel |
| | | | 11-1 | | |
| Blue | 214 | Blue 28 | 1345-16-0 | Shepherd | Cobalt and aluminum |
| Red | nubifer R- | | | Nubiola/Ferro | iron oxides |
| | 5501 | | | | |
| Green | SMM Chrome | | | Nubiola/Ferro | Chrome oxide |
| | oxide | | | | |
| Green | Green 223 | Green 50 | | Shepherd | Cobalt Titanate Green Spinel |

In certain embodiments, the composition may include at least one inorganic pigment that is not a mixed metal oxide. The pigment, a mixed metal oxide or otherwise, provides a specific color to the coating.

In certain embodiments, the composition may include an inorganic material that provides a specific property or properties such as electrical (insulative, conductive, capacitive), thermal (insulative or conductive), ferro electric, pyro electric, piezoelectric, optical refractive index, or magnetic.

In certain embodiments, the composition includes 0 to 95 weight %, particularly 5 to 30 weight %, more particularly 14 to 20 weight %, of at least one pigment and/or an inorganic material, based on the total weight of the composition including the weight of the H₂O. In certain embodiments, the composition includes 10 to 60 weight %, more particularly 28 to 40 weight %, of at least one pigment and/or an inorganic material, based on the total dry weight of the composition. In certain embodiments, the composition includes 5 to 55 weight % of at least one pigment and/or an inorganic material, based on the total dry weight of the composition. In certain embodiments, the composition includes 20 to 90 weight % of component (c) based on the total weight of the composition including the weight of the water.

The composition optionally also includes at least one water miscible liquid component. For the example, the composition optionally may include at least one water soluble solvent. Solvents may also be included in the composition to extend the open time of the coating for digital ink, spray, roll-coat, silk screen, flood coat, gravure, lithography, offset printing, flexography, or transfer printing applications. Illustrate solvents may include ammonium hydroxide, amino-2-propanol, triethanolamine, aminoethylethanolamine, ethylene diamine, aminomethylpropanol, N-methylenthanolamine, amino2-propanol, and ethanol amine.

The composition may include other optional additives such as clays, fillers, dispersing agents, suspending or settling agents (e.g., an alginate), adhesion promoters, curatives, or accelerators. Illustrative fillers include silicate, silica (e.g., fumed (pyrogenic silica), precipitated or dispersion), clays or other high temperature fillers. Illustrative dispersing agents may include carboxylic acids such as lactic acid, glycolic acid, formic acid, acetic acid, propionic acid, butyric acid, valeric acid, and caproic acid.

An additional optional additive is at least one peroxide such as sodium peroxide, potassium peroxide or lithium peroxide.

Another optional additive is phosphoric acid.

In certain embodiments, the compositions include frit particles. In certain embodiments, the compositions do not include frit particles.

In certain embodiments, the compositions do not include organic solvents, particularly volatile organic solvents (VOCs). In other embodiments, the compositions may include a very small amount (e.g., less than 25 wt %, more particularly less than 10 wt %, based on the total weight of the aqueous composition) of VOCs.

In certain embodiments, the compositions do not include any dyes.

In certain embodiments, the compositions can be applied at a pH of 3 to 12.

The compositions disclosed herein may be applied, for example, via digital ink, silk screen, spray, roll-coat, silk screen, flood coat, gravure, lithography, offset printing, flexography, or transfer printing.

The compositions may be made by mechanically mixing together (e.g., via milling) the components at room temperature. The composition may also be filtered to obtain the desired particle size. For example, the composition may be passed through at least one or more absolute filters (e.g., 20 μm, 5 μm and/or 1 μm).

In certain embodiments, the particles in the composition (e.g., pigment particles) have an average diameter of less than 10 μm, more particularly less than 5 μm, and most particularly less than 1 μm. Small particle size is important for reducing nozzle clogging in print heads due to the diameter of the nozzles.

The pigment particles in the composition may settle out of suspension over time, and thus the print head may be associated with an ink circulation system to minimize pigment drop-out. The size of the pigments and the viscosity of the composition along with other formulation modifications may be adapted such that a settling velocity of the pigments is reduced. The composition may sediment one or several times, however the composition resumes its original structure and pigment distribution by stirring, circulating or oscillating the ink.

In certain embodiments, the compositions disclosed herein are particularly useful for digital printing. By “digital printing” is meant a digitally controlled ejection or application of the composition that is used to position (ink) colorants in pre-defined patterns onto a surface. In certain embodiments, the composition may be a fluid that is ejected in the form of drops. In certain embodiments, the process involves circulating the composition within at least one piezo print head, and printing a digital image or full coverage with at least one piezo print head by applying drops of the composition onto the substrate.

In certain embodiments, the viscosity of the composition is such that the composition can be discharged from an inkjet head, especially a printer head utilizing a piezoelectric transducer to drive the ink in a controlled way for digital printing or full coverage coating. For example, the composition may have a viscosity of less than or equal to 300 cP, more particularly less than or equal to 250 cP, even more particularly less than or equal to 75 cP, and most particularly less than or equal to 30 cP. In certain embodiments, the composition may have a viscosity of 2 cP to 30 cP, more particularly 2 cP to 25 cP, and most particularly 2 cP to 20 cP. The viscosity is measured on a Brookfield RVDV-11+PX viscometer using spindle 00S at 100 rpm.

In certain embodiments, the compositions provide highly reflective coatings that have a high total solar reflection (TSR). The TSR coatings can be used for a variety of applications, but are particularly useful for improving the performance of photovoltaic cells. The coating compositions disclosed herein can bond to rutile-based titanium dioxide at high temperature without negatively altering the color as opposed to a silicate based coating that would slightly grey and reduce the TSR. These phosphate coatings are designed to provide high TSR by improving the reflectivity in both the visible and the near infrared (IR) and, optionally, in the medium and far IR. The initial range is from 300 nm to 2500 nm; however, heat generated from the ground and other sources can emit infrared wavelengths larger than 2500 nm. Dependent on the structure of a solar cell panel, the phosphate coating can be applied to the second (S2), third (S3), or fourth (S4) surface of the glass if the panel contains two glass components. Examples of a TSR formulations are shown below in Table 2.

The composition is heat curable. During curing, water is removed via evaporation with high temperature to promote bonding between the phosphate and the metal-containing ingredient and/or between the phosphate, and to the substrate surface. Curing temperature can depend on substrate requirements. For example, the curing may be at 420 to 750° C., more particularly 600 to 700° C. In another example, tempering glass requires 650 to 800° C. and will also cure the applied coating. However, a temperature as low as 600° C., or 420° C. in some embodiments, will provide acceptable cure

Illustrative glass substrates to which the compositions disclosed herein may be applied to include, but are not limited to, architectural components such as the first, second, third or fourth surface of an insulated glass unit (IGU) for commercial, industrial or residential buildings and homes; automotive glass, including both laminated and non-laminated; appliance glass; furniture glass; interior wall glass; shower divider glass; door glass; and glass used in electronics such as for photovoltaics. Glass substrates would include both tempered and non-tempered and annealed glass with thicknesses ranging from 0.005 mm to 12 mm. Illustrative types of glass include silica oxide, silicates, phosphates, and borosilicates.

Illustrative ceramic substrates include, but are not limited to, architectural components such as flooring, roofing, ceilings and walls for both exterior and interior surfaces. Illustrative types of ceramic include alumina, silicon nitride, silicon carbide, zirconia, beryllium oxide, glass-ceramics, boron carbide, silicon carbides, tungsten carbides, porcelain, carbon, graphites, composites and ceramic fibers.

Illustrative metal substrates include, but are not limited to, architectural components such as metal inserts, decorative external and internal wall and roof panels (insulated or non-insulated), metal supports, industrial components, automotive components, appliance components and electronic components. Illustrate types of metal include aluminum, zinc, copper, brass, silver, iron, titanium, manganese, bismuth, metal alloys, composites, wire, rod, flat stock, sheet, film, tubes and beams.

In certain embodiments, the thickness of the composition disposed on the substrate (after curing) may range from 0.25 to 100, more particularly from 2 to 50, and most particularly from 2 to 12, μm. In certain embodiments, the thickness of the composition disposed on the substrate (after application but prior to curing) may range from 0.05 to 200, more particularly from 0.5 to 100, and most particularly from 1 to 25 μm.

A large portion of the commercial and industrial inkjet printers use the piezoelectric print head technology. A piezoelectric crystal material (generally called “PZT” for lead zirconate titanate) in or immediately adjacent to an ink-filled chamber behind each nozzle is used to eject ink drops. When a voltage is applied, the piezoelectric material changes shape, which generates a pressure pulse in the fluid forcing a droplet of ink from the nozzle. This type of piezo print head is known as drop-on-demand (DOD). Other alternative piezo based print heads can offer multiple drop-on-demand (MDOD) and can allow for higher viscosities as well as larger solid particle size components within the silicate resin. Piezo print heads can offer a wide variety of inks and are able to handle high viscosity ink. Piezo print heads are offered by several producers and classified as small, medium and large print heads depending on the nozzle and drop size. A small print head may have a nozzle opening with a diameter of about 20 microns and may fire drops of 5-20 picolitres. Medium and large print heads have nozzle opening within the range of 30-40 microns and may fire drops of 20-100 picolitres. Cp or mPas is generally used to define the viscosity of ink-jet inks. One cp is equal to one mPas. Piezo print heads may handle inks with a viscosity of a few cp to more than 50 cp. Recently, industrial flat bed printers have been developed with an ink circulation system reducing the risk that the ink dries in the nozzle opening when the print head is not active.

The aqueous compositions disclosed herein are suitable for ink-based digital printing. “Variable data lithography printing,” or “ink-based digital printing,” or “digital offset printing,” or “spray systems” or “curtain coating” or “analog transducer driven printing”, as these terms may be used throughout this disclosure, refer to lithographic printing of variable image data for producing images on a substrate that are changeable with each subsequent rendering of an image on the substrate in an image forming process. “Variable data lithographic printing” includes offset printing of ink images using lithographic ink where the images are based on digital image data that may vary from image to image. Ink-based digital printing uses a variable data lithography printing system, or digital offset printing system. A “variable data lithography system” is a system that is configured for lithographic printing using lithographic inks and based on digital image data, which may be variable from one image to the next.

The inkjet method is not particularly limited and may be of any known system, for example, a charge control system of ejecting an ink utilizing an electrostatic attraction force, a drop on demand system of utilizing a vibration pressure of a piezo element (pressure pulse system), an acoustic inkjet system of converting electric signals into acoustic beams, irradiating them to an ink, and ejecting the ink utilizing a radiation pressure, and a thermal inkjet system of heating an ink to form bubbles and utilizing the resultant pressure (BUBBLEJET®).

In certain embodiments, a pressure generation unit (for example, piezo element) using the pressure pulse method is used, the pressure generation unit is driven to control an amount of change in volume within each pressure chamber and thereby the droplet diameter of the ink composition to be ejected from the nozzle is changed to eject the ink composition from the nozzle; and a method where the pressure generation unit is driven many times, to thereby control the number of droplets ejected from the nozzle, and plural droplets are combined before landing.

The inkjet head used in the inkjet method may be either an on-demand system or a continuous system. The ejection system includes, specifically, for example, an electric-mechanical conversion system (for example, single cavity type, double cavity type, bender type, piston type, share mode type, and shared wall type, etc.), an electric-thermal conversion system (for example, thermal inkjet type, BUBBLEJET® type, etc.), an electrostatic attraction system (for example, electric field control type, and slit jet type, etc.), and an electric ejecting system (for example, spark jet type, etc.) and any of the ejection systems may be used.

In certain embodiments, the image forming method includes, after the ink applying step, a heating fixing step for heating and fixing the ink image formed by the application of the ink composition by placing the image in contact with a heated surface. By adding a heating fixing treatment, fixing of the image on the recording medium is achieved, and the resistance of the image to abrasion and water soaking can be further enhanced.

The heating method is not particularly limited, but methods of non-contact drying such as a method of heating with a heat generator such as a nichrome wire heater; a method of supplying warm air or hot air; and a method of heating with a halogen lamp, an infrared lamp, microwave, or the like, may be suitably exemplified. The method of heating is not particularly limited, but methods of performing heating and fixing by contact such as, for example, a method of pressing a heat plate to the image-formed surface of the recording medium, and a method of passing the image through a pair of rollers using a heating and pressing apparatus equipped with a pair of heating and pressing rollers, a pair of heating and pressing belts, or a heating and pressing belt disposed on the side of the image-recorded surface of the recording medium and a retaining roller disposed on the opposite side.

In certain embodiments, after the ink composition is applied to a substrate the composition-bearing substrate is subjected to a tempering process.

Certain embodiments are described below in the following numbered clauses:

1. A heat curable aqueous composition comprising:

(a) water;

(b) at least 5 wt % sodium pyrophosphate, at least 5 wt % sodium phosphate monobasic, at least 5 wt % sodium triphosphate, at least 5 wt % monoammonium phosphate, at least 5 wt % diammonium phosphate, or at least 5 wt % of a mixture thereof, based on the total weight of the composition including the weight of the water; and

(c) at least one pigment, or at least one metal-containing ingredient, or a mixture of at least one pigment and at least one metal-containing ingredient.

2. The composition of clause 1, wherein component (b) is at least 5 wt % sodium pyrophosphate, at least 5 wt % sodium phosphate monobasic, at least 5 wt % sodium triphosphate, or at least 5 wt % of a mixture thereof.

3. The composition of clause 1 or 2, wherein the sodium pyrophosphate is sodium pyrophosphate dibasic, sodium pyrophosphate tetrabasic, or a mixture thereof.

4. The composition of clause 1, wherein the sodium pyrophosphate is sodium pyrophosphate dibasic.

5. The composition of clause 1, wherein component (b) is sodium phosphate monobasic.

6. The composition of any one of clauses 1 to 5, wherein the metal-containing ingredient is at least one transition metal compound, post transition metal compound or metalloid compound.

7. The composition of clause 6, wherein the transition metal compound is a transition metal oxide, transition metal halide, transition metal hydrate or transition metal phosphate, or the post transition metal compound is a post transition metal oxide, post transition metal halide, post transition metal hydrate or post transition metal phosphate, or the metalloid compound is a metalloid oxide, metalloid halide, metalloid hydrate.

8. The composition of any one of clauses 1 to 7, wherein the metal ingredient is at least one of titanium dioxide, manganese oxide (Mn₂O₃), iron (III) oxide, zinc oxide, aluminum oxide (Al₂O₃), bismuth aluminate hydrate or aluminum phosphate.

9. The composition of any one of clauses 1 to 8, wherein the composition includes at least 8 wt % of component (b) based on the total weight of the composition including the weight of the water.

10. The composition of any one of clauses 1 to 9, wherein the composition includes not greater than 20 wt % of component (b) based on the total weight of the composition including the weight of the water.

11. The composition of any one of clauses 1 to 10, wherein the composition includes 0.5 to 2 wt % of metal-containing ingredient (c) based on the total weight of the composition including the weight of the water.

12. The composition of any one of clauses 1 to 10, wherein the composition includes 5 to 30 wt % of pigment (c) based on the total weight of the composition including the weight of the water.

13. The composition of any one of clauses 1 to 10, wherein the composition includes 20 to 90 wt % of component (c) based on the total weight of the composition including the weight of the water.

14. The composition of any one of clauses 1 to 13, wherein the composition includes at least one pigment.

15. The composition of any one of clauses 1 to 14, wherein the composition includes at least one metal-containing ingredient.

16. The composition of any one of clauses 1 to 13, wherein the composition includes a pigment and a metal-containing ingredient that is different than the pigment.

17. The composition of clause 4, wherein the metal ingredient is at least one of titanium dioxide, manganese oxide (Mn₂O₃), iron (III) oxide, zinc oxide, aluminum oxide (Al₂O₃), bismuth aluminate hydrate or aluminum phosphate.

18. The composition of any one of clauses 1 to 13, wherein the pigment is a mixed metal oxide pigment

19. The composition of any of one of clauses 1 to 18, further comprising at least one water soluble solvent.

20. The composition of clause 19, wherein the solvent is ammonium hydroxide, amino-2-propanol, triethanolamine, aminoethylethanolamine, ethylene diamine, aminomethylpropanol, N-methylenthanolamine, amino2-propanol, or ethanol amine.

21. The composition of any one of clauses 1 to 20, wherein the composition does not include an organic polymeric film-former.

22. The composition of any one of clauses 1 to 21, wherein the composition is in the form of a digital ink.

23. The composition of any one of clauses 1 to 22, wherein the composition has a pH of 3 to 12.

24. The composition of any one of clauses 1 to 23, wherein the composition further comprises a carboxylic acid.

25. The composition of any one of clauses 1 to 24, wherein the composition further comprises a peroxide.

26. The composition of any one of clauses 1 to 25, wherein the metal-containing ingredient (c) is rutile titanium dioxide.

27. The composition of any one of clauses 1 to 26, wherein the composition includes phosphoric acid.

28. The composition of any one of clauses 1 to 27, wherein the composition includes (i) at least one of sodium pyrophosphate, sodium phosphate monobasic, or sodium triphosphate, and (ii) at least one of monoammonium phosphate or diammonium phosphate.

29. A method comprising applying the composition of any one of clauses 1 to 28 to a substrate.

30. The method of clause 29, wherein the substrate is ceramic, glass, metal, composite or wood.

31. The method of clause 29 or 30, further comprising heating the composition thereby curing composition and forming a coating.

32. The method of any one of clauses 29 to 31, wherein the composition-applied substrate is subjected to heating at a temperature of at least 420° C.

33. The method of any one of clauses 29 to 32, wherein the composition is applied to the substrate via digital ink.

34. The method of any one of clauses 29 to 32, wherein the composition is applied to the substrate via silk screen

35. The method of any one of clauses 29 to 32, wherein the composition is applied to the substrate via spray.

36. The method of any one of clauses 29 to 32, wherein the composition is applied to the substrate via roll-coat.

37. The method of any one of clauses 29 to 32, wherein the composition is applied to the substrate via flood coat

38. The method of any one of clauses 29 to 32, wherein the composition is applied to the substrate via gravure.

39. The method of any one of clauses 29 to 32, wherein the composition is applied to the substrate via lithography.

40. The method of any one of clauses 29 to 32, wherein the composition is applied to the substrate via offset printing.

41. The method of any one of clauses 29 to 32, wherein the composition is applied to the substrate via flexography

42. The method of any one of clauses 29 to 32, wherein the composition is applied to the substrate via transfer printing.

43. The method of any one of clauses 29 to 32, wherein the composition is applied to at least one component of a solar cell panel.

44. An article comprising a substrate and a coating disposed on a surface of the substrate, wherein the coating is formed from any one of the compositions of clauses 1 to 28.

45. The article of clause 44, wherein the coating is bonded onto the surface of the substrate.

46. The article of clause 44, wherein the substrate is ceramic, glass, metal, composite or wood.

47. The article of clause 44, wherein the substrate is a photovoltaic cell.

48. The article of clause 44, wherein the substrate is a solar cell panel.

### EXAMPLES

Examples of illustrative compositions are shown below. These examples were made by mixing the ingredients together at room temperature. The amounts shown are weight percentage based on the total weight of the composition for Examples 1-7 and in grams for formulations A-G shown below in Table 2.

### Example 1

Sodium pyrophosphate 15.3%

### Zinc Oxide 0.9%

### H₂O 49.8%

Ammonium hydroxide 6.9%
Silica dispersion 7.1%
Black pigment 20.0%

### Example 2

Sodium pyrophosphate 11.4%

### Zinc Oxide 0.6%

### H₂O 56.1%

Ammonium hydroxide 5.1%
Silica dispersion 4.5%

### Pigment 22%

### Dowfax 2A1 Surfactant 0.3%

### Example 3

Sodium pyrophosphate 15.6%

### Zinc Oxide 0.7%

### H₂O 53.4%

Ammonium hydroxide 6.7%

### 30C965 23.6%

### Example 4

Sodium pyrophosphate 12.3%
Ammonium hydroxide 5.5%

### Zinc Oxide 0.6%

### H₂O 53.2%

Ethylene glycol 2.0%
Silica dispersion 5.4%

### 30C965 21.0%

### Example 5

Sodium pyrophosphate 18.2%

### H₂O 31.1%

Ammonium hydroxide 7.8%
Silica dispersion 10.4%

### Pigment 31.9%

Aluminum oxide 0.6%

### Surfactant (Niaproof 08) 0.016

### Example 6

| | |
|---|---|
| H₂O | 52% |
| Na pyrophosphate | 15% |
| Ammonium hydroxide | 6.9% |
| TiO₂ (white pigment) | 26% |
| Dowfax 2A1 (Surfactant) | 0.10% |

### Example 7

| | |
|---|---|
| Alginate .3% in H₂O | 49.3% |
| black pigment | 19.2% |
| Neosperse FX600 | 0.2% |
| Na phosphate monobasic | 11.5% |
| water | 12.5% |
| silica dispersion | 6.6% |
| Dowfax 2A1 (surfactant) | 0.7% |

TABLE 2
Formulations A-G

| Compounds | Form. A | Form. B | Form. C | Form. D | Form. E | Form. F | Form. G |
|---|---|---|---|---|---|---|---|
| Water | 10 to 40 | 10 to 40 | 10 to 40 | 10 to 40 | 15 to 30 | 15 to 30 | 15 to 30 |
| Sodium phosphate | 4.5 | 6.3 | 6 | 1 | 1.5 | 1.5 | 1.8 |
| Phosphoric acid | 1.2 | 0.8 | 0 | 0.2 | 0.2 | | |
| mono ammonium phosphate | | | | 3.5 | 3 | 2.5 | 2 |
| di ammonium phosphate | 1.8 | 1.8 | 1.8 | | | | |
| silica | 3.2 | 4 | 3.2 | 1.5 | 1.3 | 1.5 | 1.2 |
| Titanium dioxide (type 1) | 12.00 | 10.00 | 12.00 | 6 | 6 | 10 | 12 |
| Titanium dioxide (type 2) | | | | 6 | 6 | | |

The sodium phosphate in formulations A-G may be sodium pyrophosphate or sodium phosphate monobasic.

In view of the many possible embodiments to which the principles of the disclosed invention may be applied, it should be recognized that the illustrated embodiments are only preferred examples of the invention and should not be taken as limiting the scope of the invention.

What is claimed is:

1. A heat curable aqueous composition comprising:
(a) water;
(b) at least 5 weight % sodium pyrophosphate, at least 5 weight % sodium phosphate monobasic, at least 5 weight % sodium triphosphate, at least 5 weight % monoammonium phosphate, at least 5 weight % diammonium phosphate, or at least 5 weight % of a mixture thereof, based on the total weight of the composition including the weight of the water; and
(c) at least one pigment, or at least one metal-containing ingredient, or a mixture of at least one pigment and at least one metal-containing ingredient.

2. The composition of claim 1, wherein component (b) is at least 5 weight % sodium pyrophosphate, at least 5 weight % sodium phosphate monobasic, at least 5 weight % sodium triphosphate, or at least 5 weight % of a mixture thereof.

3. The composition of claim 1, wherein the composition includes sodium pyrophosphate and the sodium pyrophosphate is sodium pyrophosphate dibasic, sodium pyrophosphate tetrabasic, or a mixture thereof.

4. The composition of claim 1, wherein the composition includes sodium pyrophosphate and the sodium pyrophosphate is sodium pyrophosphate dibasic.

5. The composition of claim 1, wherein component (b) is sodium phosphate monobasic.

6. The composition of claim 1, wherein the composition includes the metal-containing ingredient and the metal-containing ingredient is at least one transition metal compound, post transition metal compound or metalloid compound.

7. The composition of claim 6, wherein the transition metal compound is a transition metal oxide, transition metal halide, transition metal hydrate or transition metal phosphate, or the post transition metal compound is a post transition metal oxide, post transition metal halide, post transition metal hydrate or post transition metal phosphate, or the metalloid compound is a metalloid oxide, metalloid halide, metalloid hydrate.

8. The composition of claim 1, wherein the composition includes the metal-containing ingredient and the metal-containing ingredient is at least one of titanium dioxide, manganese oxide (Mn₂O₃), iron (III) oxide, zinc oxide, aluminum oxide (Al₂O₃), bismuth aluminate hydrate or aluminum phosphate.

9. The composition of claim 1, wherein the composition includes at least 8 weight % of component (b) based on the total weight of the composition including the weight of the water.

10. The composition of claim 1, wherein the composition includes not greater than 20 weight % of component (b) based on the total weight of the composition including the weight of the water.

11. The composition of claim 1, wherein the composition includes 0.5 to 2 weight % of metal-containing ingredient (c) based on the total weight of the composition including the weight of the water.

12. The composition of claim 1, wherein the composition includes 5 to 55 weight % of pigment (c) based on the total weight of the composition including the weight of the water.

13. The composition of claim 1, wherein the composition includes 20 to 90 weight % of component (c) based on the total weight of the composition including the weight of the water.

14. The composition of claim 4, wherein the composition includes at least one metal-containing ingredient and the metal ingredient is at least one of titanium dioxide, manganese oxide (Mn₂O₃), iron (III) oxide, zinc oxide, aluminum oxide (Al₂O₃), bismuth aluminate hydrate or aluminum phosphate.

15. The composition of claim 1, wherein the metal-containing ingredient (c) is rutile titanium dioxide or anatase titanium dioxide.

16. The composition of claim 1, wherein the composition includes phosphoric acid.

17. The composition of claim 1, wherein the composition includes (i) at least one of sodium pyrophosphate, sodium phosphate monobasic, or sodium triphosphate, and (ii) at least one of monoammonium phosphate or diammonium phosphate.

18. A method comprising applying the composition of claim 1 to a substrate.

19. The method of claim 18, wherein the composition is applied via silk screen, roll coat, spray, digital ink or flood coat.

20. An article comprising a substrate and a coating disposed on a surface of the substrate, wherein the coating is formed from the composition of claim 1.

21. The article of claim 20, wherein the substrate is a photovoltaic cell.
